(19) United States
(12) Patent Application Publication
(10) Pub. No.: US 2026/0278219 A1
(43) Pub. Date: Sep. 17, 2026

(54) COMPUTATION DEVICE FOR ROBOT SYSTEM

(71) Applicant: FANUC CORPORATION, Minamitsuru-gun, Yamanashi (JP)

(72) Inventors: Masumi ONO, Yamanashi (JP); Yutaro IMASHIRO, Yamanashi (JP); Hiroshi NAKAGAWA, Yamanashi (JP)

(73) Assignee: FANUC CORPORATION, Minamitsuru-gun, Yamanashi (JP)

(21) Appl. No.: 19/471,419

(22) PCT Filed: Apr. 17, 2023
(86) PCT No.: PCT/JP2023/015384

§ 371 Date: Oct. 1, 2025

(51) Int. Cl. G06F 30/27

(52) U.S. Cl. CPC G06F 30/27

(57) ABSTRACT

A computation device for simulating a robot system includes at least one processor and at least one memory. The memory stores a mathematical model in which at least one of a robot, a tool, or a work object is defined as an elastic element. The processor acquires input information including the orientation of the robot, the placement of the tool and the work object, and the size and direction of the force and/or the torque of the tool or the work object, and estimates a load or a deformation amount for at least one of the robot, the tool, or the work object by using the acquired input information and the mathematical model stored in the memory.

This application is a national phase of International Application No. PCT/JP2023/015384, filed Apr. 17, 2023, which is incorporated herein by reference in its entirety.

### TECHNICAL FIELD

The present disclosure relates to a computation device for a robot system.

### BACKGROUND ART

There is a known simulation device that takes into account the contact force caused by contact between a robot and a workpiece associated with the operation of the robot to calculate the load acting on each joint of the robot (for example, see PTL 1).

### CITATION LIST

### Patent Literature

{PTL 1} Japanese Unexamined Patent Application, Publication No. 2018-030210

### SUMMARY OF INVENTION

An aspect of the present disclosure is a computation device for simulating a robot system comprising a robot having a plurality of joints and a tool attached to the robot and configured to perform a predetermined task on a workpiece, the task being performed by causing at least one of a force or a torque generated by one of the tool or the workpiece to act on an other, the computation device comprising: at least one processor; and at least one memory, wherein the memory stores a mathematical model in which at least one of the robot, the tool, or the workpiece is defined as an elastic element, and the processor acquires input information including a posture of the robot, an arrangement of the tool and the workpiece, and a magnitude and a direction of at least one of the force or the torque and estimates a load or an amount of deformation in at least one of the robot, the tool, or the workpiece by using the acquired input information and the mathematical model stored in the memory.

### BRIEF DESCRIPTION OF DRAWINGS

FIG. 1 is a side view of a robot system to which a computation device according to an embodiment of the present disclosure is applied.

FIG. 2 is a perspective view of a nut runner of the robot system in FIG. 1.

FIG. 3 is a block diagram illustrating the computation device according to the embodiment of the present disclosure.

FIG. 4 schematically illustrates a dynamic model corresponding to the robot system in FIG. 1.

FIG. 5 is a front view of a display unit of the computation device according to the embodiment of the present disclosure.

FIG. 6 is a flowchart of an operation of the computation device according to the embodiment of the present disclosure.

### DESCRIPTION OF EMBODIMENTS

A computation device 1 that performs a simulation of a robot system 10 according to an embodiment of the present disclosure will be described below with reference to the drawings.

First, the robot system 10 to which the computation device 1 of this embodiment is applied will be described.

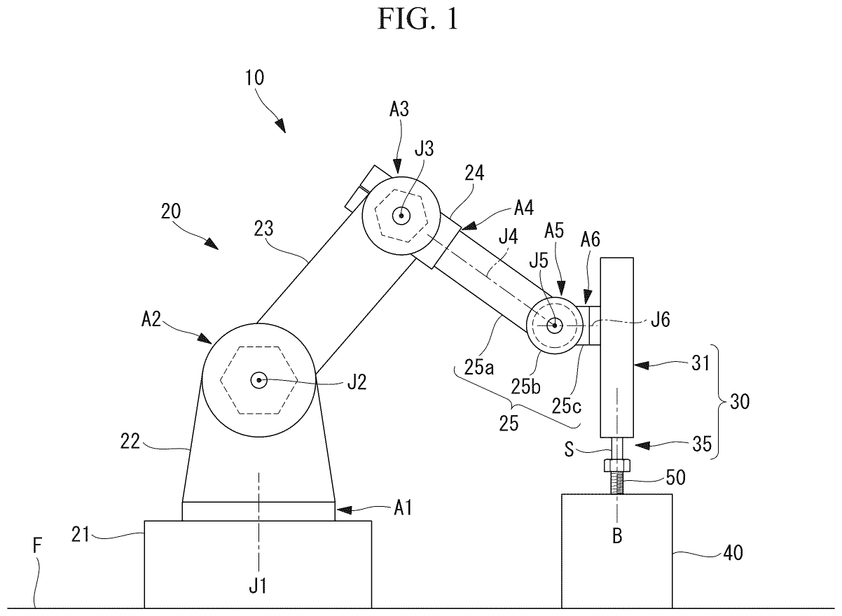

As illustrated in FIG. 1, the robot system 10 is, for example, a screw fastening system including a robot 20 fixed to a horizontal floor F and a nut runner (tool) 30 attached to the robot 20. In this case, the robot system 10 also includes a workpiece 40 that is fixed to the floor F and to which a screw 50 is fastened by the nut runner 30. In other words, the robot 20, the nut runner 30, the workpiece 40, and the floor F, which constitute the robot system 10, form a closed loop.

The robot 20 is, for example, a six-axis articulated type robot, and includes a base 21 installed on the floor F and a revolving drum 22 supported so as to be rotatable about a vertical first axis J1 with respect to the base 21. The robot 20 includes a first arm 23 supported so as to be rotatable about a horizontal second axis J2 with respect to the revolving drum 22, and a second arm 24 supported so as to be rotatable about a horizontal third axis J3 with respect to the distal end of the first arm 23. The robot 20 further includes a three-axis wrist unit 25 supported at the distal end of the second arm 24.

The wrist unit 25 includes a first wrist element 25a supported so as to be rotatable with respect to the second arm 24 about a fourth axis J4 extending along a plane orthogonal to the third axis J3. The wrist unit 25 also includes a second wrist element 25b supported so as to be rotatable with respect to the first wrist element 25a about a fifth axis J5 orthogonal to the fourth axis J4. The wrist unit 25 further includes a third wrist element 25c supported so as to be rotatable with respect to the second wrist element 25b about a sixth axis J6 orthogonal to the fifth axis J5 and intersecting the fourth axis J4.

In other words, the robot 20 includes six joints A1 to A6.

As illustrated in FIG. 1, the nut runner 30 includes, for example, a body part 31 fixed to the distal end of the third wrist element 25c and a socket part 35 connected to the distal end of the body part 31.

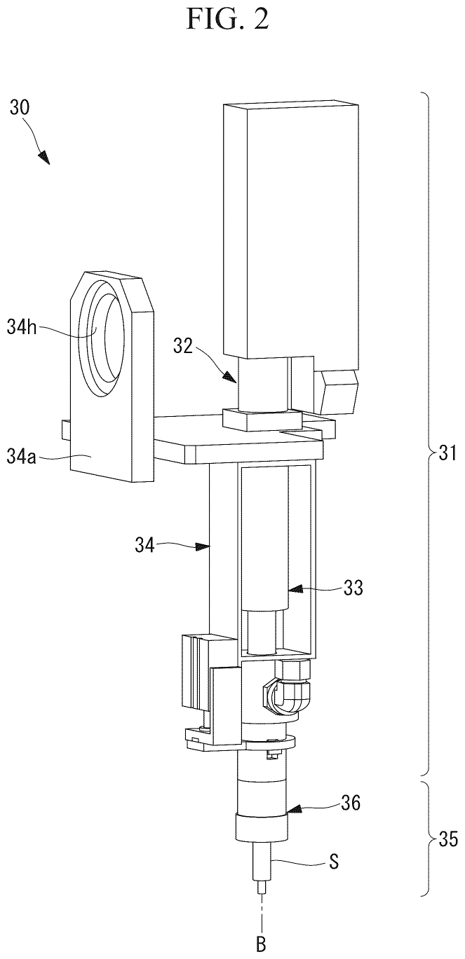

As illustrated in FIG. 2, the body part 31 includes a motor 32, a drive shaft 33 rotated about the axis B by the motor 32, and a box-shaped frame 34 surrounding the drive shaft 33. Furthermore, an attachment part 34a having an attachment hole 34h extending in a direction orthogonal to the axis B is fixed to the proximal side of the frame 34. By fitting and fixing the distal end of the third wrist element 25c of the robot 20 to the attachment hole 34h, the nut runner 30 is attached to the robot 20 such that the axis B is orthogonal to the sixth axis J6.

The socket part 35 includes a housing 36 extending along the axis B and coaxially connected to the distal end of the drive shaft 33. The housing 36 has a hole (not illustrated) centered on the axis B at the distal end thereof, and a tool S corresponding to the screw 50 to be fastened to the workpiece 40 is detachably fitted into the hole. Specifically, when the motor 32 in the body part 31 is actuated, the housing 36 and the tool S rotate about the axis B integrally with the drive shaft 33.

The socket part 35 is provided with a screw supply mechanism (not illustrated) for supplying screws 50 one by one to the tip of the tool S and engaging the heads of the screws 50 with the tip of the tool S.

As illustrated in FIG. 1, in the robot system 10, the screw 50 attached to the tool S can be arranged at a predetermined fastening position with respect to the workpiece 40 by actuating the joints A1 to A6 of the robot 20. Then, in this state, the motor 32 for the nut runner 30 is actuated to rotate the tool S about the axis B. As a result, the screw fastening task of fastening the screw 50 to the workpiece 40 with a predetermined fastening torque is performed.

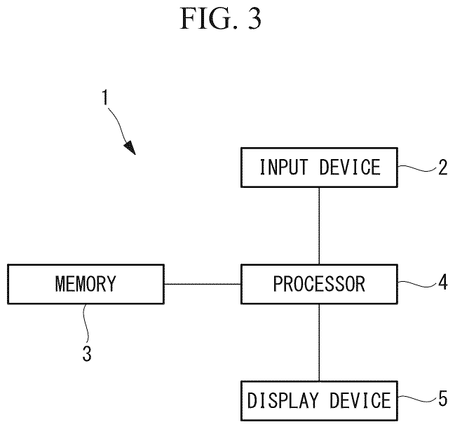

Next, the computation device 1 according to this embodiment will be described. The computation device 1 is, for example, an offline computer that simulates the operation of the robot system 10. As illustrated in FIG. 3, the computation device 1 includes an input device 2, at least one memory 3 such as a ROM or a RAM, at least one processor 4 such as a CPU, and a display unit 5.

The input device 2 includes a keyboard, a touch panel, an operating panel, or the like and receives input information about the robot system 10 input by an operator. In this case, the input information includes, for example, information about the posture of the robot 20, the arrangement of the nut runner 30 and the workpiece 40, and the magnitude and direction of the fastening torque exerted by the motor 32 for the nut runner 30.

The memory 3 stores in advance a mathematical model corresponding to the robot system 10, and the basic information on the robot system 10.

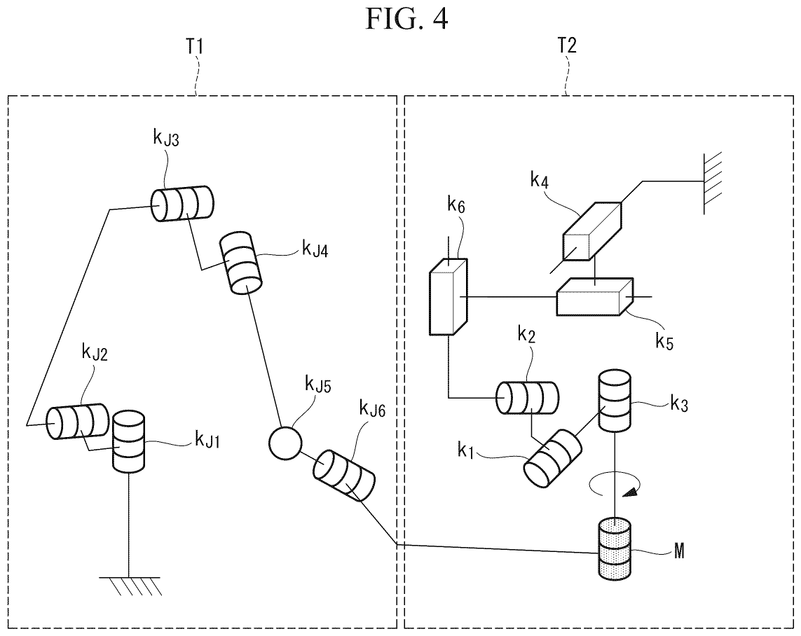

The mathematical model is set based on a dynamic model constructed by defining the robot system 10 with multiple elastic elements connected to one another, for example, as illustrated in FIG. 4.

The basic information of the robot system 10 includes, for example, the distances between the joints A1 to A6, the moduli of elasticity indicating the rigidities of the joints A1 to A6 of the robot 20, and the moduli of elasticity indicating the rigidities of the nut runner 30 and the workpiece 40.

The dynamic model illustrated in FIG. 4 represents, with multiple rotational elastic elements and linear elastic elements connected by rigid links, the mechanisms arranged between the base 21 fixed to the floor F and the workpiece 40 fixed to the floor F.

More specifically, in the dynamic model, the six joints A1 to A6 of the robot 20 are respectively defined as single rotational elastic elements k_{J1} to k_{J6}. The nut runner 30 and the workpiece 40 are defined by an input element M that generates a fastening torque and a combination of three rotational elastic elements k₁ to k₃ and three linear elastic elements k₄ to k₆.

Specifically, the dynamic model includes a robot area T1 corresponding to the robot 20 and a nut runner area T2 corresponding to the nut runner 30 and the workpiece 40.

Next, an example mathematical model derived based on the dynamic model illustrated in FIG. 4 will be described below.

$$\begin{matrix}\{ Exp . 1 \} & \\ [ \begin{matrix}{f}_{N} \\ {m}_{N}\end{matrix} ] = [ \begin{matrix}O & {I}_{3} \\ {I}_{3} & O\end{matrix} ] {( {I}_{6} + {K}_{N R} {J ( {K}_{R B} )}^{- 1} {J}^{T} )}^{- 1} [ \begin{matrix}O & {I}_{3} \\ {I}_{3} & O\end{matrix} ] [ \begin{matrix}0 \\ {M}_{T}\end{matrix} ] & ( 1 )\end{matrix}$$

where
f_{N} is a force acting on the linear elastic elements k₄ to k₆,
m_{N} is a moment acting on the rotational elastic elements k₁ to k₃,
I₃ is a third order identity matrix,
I₆ is a sixth order identity matrix,
K_{NR} is an elasticity matrix indicating the rigidities of the rotational elastic elements k₁ to k₃ and the linear elastic elements k₄ to k₆,
J is a Jacobian matrix with the amounts of deformation of the rotational elastic elements k_{J1} to k_{J6} as the inputs and the amounts of deformation of the rotational elastic elements k₁ to k₃ and the linear elastic elements k₄ to k₆ as the outputs,
K_{RB} is an elasticity matrix indicating the rigidities of the rotational elastic elements k_{J1} to k_{J6}, and
M_{T} is a vector value of the fastening torque input by the input element M.

$$\begin{matrix}\{ Exp . 2 \} & \\ [ \begin{matrix}{f}_{n} \\ {m}_{n}\end{matrix} ] = [ \begin{matrix}{I}_{3} & O \\ {[ {P}_{n} {P}_{n + 1} ]}_{\times } & {I}_{3}\end{matrix} ] [ \begin{matrix}{f}_{n + 1} \\ {m}_{n + 1}\end{matrix} ] ( n = 6 , … , 1 ) & ( 2 )\end{matrix}$$

where
fₙ (n=1, . . . , 6) is a force acting on the n-th joint among the joints A1 to A6, and f₇ is a force acting on the hand position of the robot 20,
mₙ (n=1, . . . , 6) is a moment acting on the n-th joint among the joints A1 to A6, and m₇ is a moment acting on the hand position of the robot 20, and
Pₙ (n=1, . . . , 6) is the position of the n-th joint among the joints A1 to A6, and P₇ is the hand position of the robot 20.

Expression (1) expresses, with the fastening torque M_{T} and the elasticity matrices K_{RB} and K_{NR} in the robot area T1 and the nut runner area T2, respectively, the force f_{N} and the moment m_{N} acting on the elastic elements k₁ to k₆ in the nut runner area T2. Expression (1) is derived by solving a force equilibrium equation based on an assumption that the force IN and the moment my acting on the elastic elements k₁ to k₆ and the amounts of deformation of the elastic elements k₁ to k₆ follow Hooke's law.

Furthermore, the force f_{N} and the moment my acting on the elastic elements k₁ to k₆ in the nut runner area T2, calculated by Expression (1), can be regarded as a force f₇ and a moment m₇ acting on the hand position of the robot 20, according to the law of action and reaction.

Accordingly, by calculating the equilibrium equation of the links connecting the rotational elastic elements k_{J1} to k_{J6}, as in Expression (2), in sequence from the hand side, the loads acting on the joints A1 to A6 can be obtained.

In this case, the elasticity matrix K_{RB} in Expression (1) above is defined based on the moduli of elasticity of the joints A1 to A6 included in the basic information on the robot system 10 stored in the memory 3. Similarly, the elasticity matrix K_{NR} in Expression (1) above is defined based on the moduli of elasticity of the nut runner 30 and the workpiece 40 included in the basic information on the robot system 10.

Furthermore, the fastening torque M_{T} and the joint position Pₙ in Expressions (1) and (2) above are both set based on the input information input by the operator.

Furthermore, the memory 3 stores allowable values for the loads acting on the joints A1 to A6. Each allowable values is determined by the load resistances set for the members, such as a motor, a speed reducer, and a bearing, constituting each of the joints A1 to A6.

The processor 4 retrieves the mathematical model from the memory 3 and calculates the retrieved mathematical model based on the input information input from the input device 2 to calculate the loads acting on the joints A1 to A6 of the robot 20.

The processor 4 also retrieves the allowable values of the joints A1 to A6 stored in the memory 3 and compares the a with the calculated loads acting on the joints A1 to A6 to determine whether the loads acting on the joints A1 to A6 exceed the allowable values. Then, the processor 4 transmits the determination results to the display unit 5 together with the proportions of the loads with respect to the allowable values.

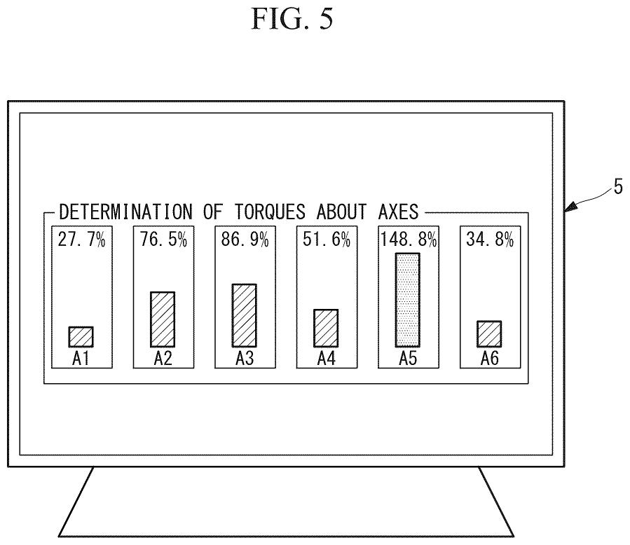

The display unit 5 is, for example, a monitor, and displays the proportions sent from the processor 4 in association with the joints A1 to A6, as illustrated in FIG. 5. When the display unit 5 receives, from the processor 4, a determination result indicating that there is one or more joints subjected to a load higher than the allowable value, the display unit 5 displays the proportion corresponding to the joint in a display color different from the display color of the other proportions.

The operation of the thus-configured computation device 1 according to this embodiment will be described below.

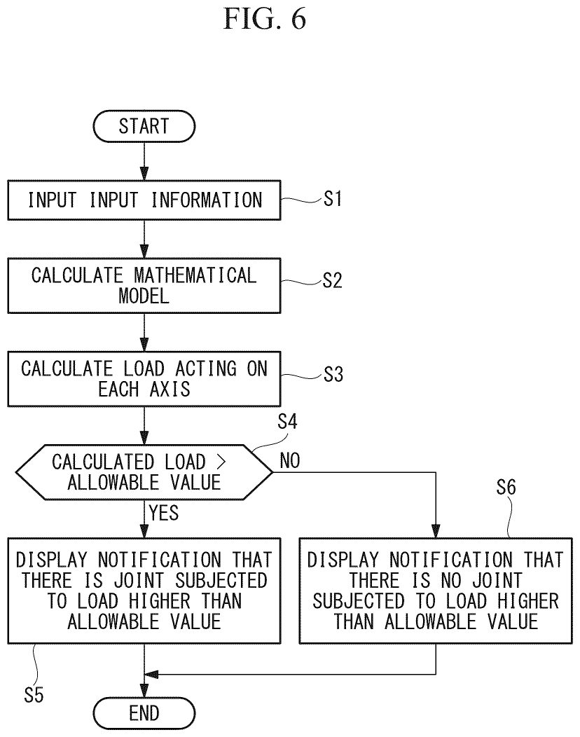

Referring to the flowchart in FIG. 6, a method of calculating the loads acting on the joints A1 to A6 of the robot system 10 that performs a screw fastening task by operating the nut runner 30, as illustrated in FIG. 1, will be described as an example.

First, the operator operates the input device 2 to input the input information on the robot system 10 (step S1). As a result, the processor 4 acquires the posture of the robot 20, i.e., the angles of the joints A1 to A6, during the screw fastening task, the arrangement of the nut runner 30 and the workpiece 40, and the magnitude and direction of the fastening torque of the nut runner 30.

Next, the processor 4 retrieves the mathematical model preliminarily stored in the memory 3, and calculates the mathematical model based on the input information input via the input device 2 (step S2).

Specifically, first, as described above, the values of the elasticity matrices K_{RB} and K_{NR}, the Jacobian matrix J, and the fastening torque M_{T} are set based on the basic information on the robot system 10 stored in the memory 3 and the input information input by the operator. Then, by calculating Expression (1), the forces IN and my acting in the nut runner area T2, that is, the load acting on the hand position of the robot 20, are obtained.

Next, the loads acting on the joints A1 to A6 are calculated by calculating Expression (2) sequentially from the joints on the distal side of the robot 20 based on the basic information and the input information. Then, the load caused by the weights of the robot 20 and the nut runner 30 is added to the calculated loads acting on the joints A1 to A6.

Through this calculation, the processor 4 calculates the magnitudes of the loads acting on the joints A1 to A6 of the robot 20 due to the counterforce of the fastening torque generated when the nut runner 30 operates (step S3).

Thereafter, the processor 4 retrieves the allowable values for the joints A1 to A6 from the memory 3, and compares the allowable values with the loads acting on the joints A1 to A6 calculated using the mathematical model (step S4). The processor 4 also calculates the proportions of the calculated loads acting on the joints A1 to A6 with respect to the allowable values.

When the result of the determination shows that there is at least one or more joints subjected to a load higher than the allowable value, the processor 4 transmits, to the display unit 5, a signal indicating to that effect and the proportions of the loads with respect to the allowable values.

The display unit 5 displays the proportions received from the processor 4 in percentages. In this case, the display unit 5 displays the proportion at the joint subjected to the load higher than the allowable value, that is, the proportion exceeding 100%, in a display color different from the display color of the other proportions.

In this way, the display unit 5 indicates that at least one of the joints A1 to A6 is subjected to the load higher than the allowable value (step S5).

Hence, the operator can know, by checking the display unit 5, that at least one of the joints A1 to A6 may be subjected to an excessive load when the robot system 10 is caused to perform the scheduled screw fastening task.

When the result of the determination by the processor 4 shows that there is no joint subjected to a load higher than the allowable value, the processor 4 transmits, to the display unit 5, a signal indicating that effect and the proportions of the loads with respect to the allowable values.

Then, the display unit 5 displays the proportions received from the processor 4 in percentages, in the same way as above. However, in this case, no proportion exceeds 100%, so, the proportions are displayed in the same color. The display unit 5 displays a notification that none of the joints A1 to A6 is subjected to the load higher than the allowable values (step S6).

This enables the operator to easily know, by checking the display unit 5, that none of the joints A1 to A6 is subjected to an excessive load even when the robot system 10 is caused to perform the scheduled screw fastening task.

As described above, with the computation device 1 according to this embodiment, it is possible to perform a simulation based on a dynamic model including not only the robot 20 but also the nut runner 30 and the workpiece 40. Hence, even in the robot system 10 in which the nut runner 30 operates as illustrated in FIG. 1, the loads acting on the joints A1 to A6 of the robot 20 due to the operation of the nut runner 30 can be accurately estimated.

This enables the operator to grasp the possibility of the joints A1 to A6 being subjected to an excessive load due to an external force input independently of the operation of the robot 20.

In this embodiment, the display unit 5 displays, in percentages, the proportions of the loads acting on the joints A1 to A6 with respect to the allowable values calculated by the processor 4, but the present invention is not limited thereto.

For example, the display unit 5 may simply display a message or the like indicating the joint subjected to a load higher than the allowable value, without displaying the proportions of the loads acting on the joints A1 to A6 with respect to the allowable values.

In this embodiment, the display unit 5 is a monitor for displaying the proportions calculated by the processor 4. Alternatively, the display unit 5 may be a user interface, such as a touch panel, that also has the function of the input device 2, that is, the function of receiving input of the input information by the operator.

In this case, for example, the display area of the display unit 5 may be divided into two areas, and an icon for receiving input of the input information and the input information that has been input may be displayed in one of the two areas, and the calculated proportions may be displayed in the other area.

This enables the operator to confirm the result of the simulation and the input information used for the simulation in association with each other. Furthermore, based on the confirmed simulation result, the operator can easily change the input information and perform the simulation again.

Hence, the operator can easily grasp the relationship between the input information and the loads acting on the joints A1 to A6, and can easily review the conditions in the screw fastening task of the robot system 10.

In this embodiment, the display unit 5 may display a 3D model indicating the target robot system 10 or a dynamic model corresponding to the target robot system 10.

This enables the operator to more intuitively grasp the joint that is assumed to be subjected to a load higher than the allowable value, making it easy to review the conditions in the screw fastening task, as in the case above.

In this embodiment, the mathematical model stored in the memory 3 is derived based on the dynamic model illustrated in FIG. 4, but the dynamic model used to derive the mathematical model is not limited thereto.

For example, the dynamic model may be one in which the joints A1 to A6 of the robot 20 are respectively defined by the combinations of the elastic elements k_{J1} to k_{J6} in the rotation directions and the elastic elements in the directions intersecting the axes, i.e., the axis inclination directions. This makes it possible to more accurately simulate the loads acting on the robot 20.

In this embodiment, even when the nut runner 30 and the workpiece 40 are not defined as the elastic elements in the dynamic model, a calculation result that is not much different from the case where the nut runner 30 and the workpiece 40 are defined as the elastic elements may be obtained. For example, in the dynamic model illustrated in FIG. 4, among the elastic elements k₁ to k₆, the elastic elements whose rigidities are assumed to be sufficiently larger than the rigidity of the robot 20 are replaced with rigid elements, that is, the moduli of elasticity of the elastic elements are set to infinity. Meanwhile, among the elastic elements k₁ to k₆, the elastic elements whose rigidities are assumed to be sufficiently smaller than the rigidity of the robot 20 are replaced with free elements, that is, the moduli of elasticity of the elastic elements are set to zero. When all of the elastic elements k₁ to k₆ are replaced with rigid elements or free elements, a dynamic model in which the nut runner 30 and the workpiece 40 are not defined as elastic elements is constructed. The use of this dynamic model can simplify the calculation of the mathematical model.

In this embodiment, the processor 4 calculates the loads acting on the joints A1 to A6, but instead of this, the processor 4 may calculate the amount of deformation of the joints A1 to A6 defined as the elastic elements.

Furthermore, in this embodiment, the processor 4 may calculate the load or the amount of deformation of a member other than the joints A1 to A6 of the robot 20, or may calculate the load or the amount of deformation of the nut runner 30 or the workpiece 40. In this case, the processor 4 may derive a mathematical model based on a dynamic model in which the target portion is defined as the elastic element.

Furthermore, in this embodiment, when it is estimated that there is one or more joints, among the joints A1 to A6, subjected to a load higher than the allowable value, the processor 4 may search for a posture of the robot 20 that reduces the load acting on that joint.

In this case, the search for the posture can be performed by the following method. The robot system 10 can perform the screw fastening task also by rotating the nut runner 30 about the axis B. Meanwhile, because the robot 20 has six degrees of freedom, the robot 20 can take a posture that is taken when the nut runner 30 is rotated about the axis B. Hence, the processor 4 performs a simulation again for the posture of the robot 20 in which the nut runner 30 is slightly rotated about the axis B, and compares the calculated loads acting on the joints A1 to A6 with the allowable values.

By repeating this operation, it is possible to search for the posture of the robot 20 in which the proportions of the loads acting on the joints A1 to A6 with respect to the allowable values are minimum.

This enables the operator to easily review the posture of the robot 20 during the screw fastening task based on the search results obtained by the computation device 1.

In this embodiment, when it is estimated that there is one or more joints subjected to a load higher than the allowable value, the processor 4 may search for an arrangement of the nut runner 30 and the workpiece 40 that reduces the load.

In this embodiment, when the actually measured values of the loads acting on the joints A1 to A6 are available, the processor 4 may acquire the actually measured values. Then, the processor 4 adjusts the values of the elasticity matrices K_{RB} and K_{NR} in the mathematical model such that the differences between the acquired actually measured values and the calculated loads acting on the joints A1 to A6 are minimum, and stores the mathematical model in the memory 3.

This further improves the accuracy of the next and subsequent simulations performed by the processor 4. In other words, the processor 4 is provided with a learning function.

In this embodiment, the processor 4 compares the loads acting on the joints A1 to A6 with the allowable values determined by the load resistances of the members constituting the joints A1 to A6. Alternatively, the processor 4 may compare each load with a threshold value calculated based on the corresponding allowable value, for example, a value obtained by multiplying each allowable value by a safety factor greater than 0 and less than or equal to 1.

This enables the operator to evaluate the loads acting on the joints A1 to A6 with margins with respect to the allowable values. Thus, it is possible to reliably prevent the joints A1 to A6 from being subjected to loads higher than or equal to the allowable values.

In this embodiment, the computation device 1 is used in a screw fastening system in which the nut runner 30 is attached to the tip of the wrist of the robot 20, but the system is not limited thereto.

For example, the computation device 1 can be applied to a robot system in which a tool, such as an engraving machine, a polishing tool, or a drill, having a power source is attached to the tip of the wrist of the robot 20.

In addition, in this embodiment, the computation device 1 is used in the robot system 10 in which the nut runner 30 operates. Instead, the computation device 1 may be used in the robot system 10 that executes a predetermined task by operating the workpiece 40.

In this embodiment, the computation device 1 is an offline computer. Instead, the computation device 1 may be integral with a controller for controlling the robot system 10.

Although the embodiment of the present disclosure has been described in detail above, the present disclosure is not limited to the above-described embodiment. Various additions, substitutions, changes, partial deletions, and the like can be made to this embodiment without departing from the spirit of the invention, or without departing from the spirit and scope of the invention derived from the contents described in the claims and equivalents thereof. For example, in the above-described embodiment, the order of operations and the order of processes are described as examples and are not exhaustive.

Additional features related to the above-described embodiment and modification will be disclosed below.

### (Appendix 1)

A computation device for simulating a robot system comprising a robot having a plurality of joints and a tool attached to the robot and configured to perform a predetermined task on a workpiece, the task being performed by causing at least one of a force or a torque generated by one of the tool or the workpiece to act on an other, the computation device comprising: at least one processor; and at least one memory, wherein the memory stores a mathematical model in which at least one of the robot, the tool, or the workpiece is defined as an elastic element, and the processor acquires input information including a posture of the robot, an arrangement of the tool or the workpiece, and a magnitude and a direction of at least one of the force and the torque and estimates a load or an amount of deformation in at least one of the robot, the tool, or the workpiece by using the acquired input information and the mathematical model stored in the memory.

### (Appendix 2)

The computation device for the robot system according to Appendix 1, wherein the processor determines whether or not the estimated load or amount of deformation is within a range of allowable values in each of the corresponding joints.

### (Appendix 3)

The computation device for the robot system according to Appendix 2, further comprising a display unit that displays a proportion of the estimated load or amount of deformation with respect to the allowable value.

### (Appendix 4)

The computation device for the robot system according to Appendix 3, wherein the display unit comprises a user interface that receives input of the input information.

### (Appendix 5)

The computation device for the robot system according to any one of Appendices 2 to 4, wherein the processor searches for a posture of the robot that reduces the load when the estimated load is higher than the allowable value.

### (Appendix 6)

The computation device for the robot system according to any one of Appendices 2 to 4, wherein the processor searches for an arrangement of the tool or the workpiece that reduces the load when the estimated load is higher than the allowable value.

### (Appendix 7)

The computation device for the robot system according to any one of Appendices 1 to 6, wherein the processor acquires an actually measured value corresponding to the load or the amount of deformation, and adjusts, by using machine learning, a value corresponding to the elastic element in the mathematical model so that the load or the amount of deformation is closer to the actually measured value.

### REFERENCE SIGNS LIST

1 Computation device
3 Memory
4 Processor
5 Display unit
10 Robot system
20 Robot
30 Nut runner (tool)
40 Workpiece
A1, A2, A3, A4, A5, A6 Joint
k_{J1}, k_{J2}, k_{J3}, k_{J4}, k_{J5}, k_{J6} Rotational elastic element
k₁, k₂, k₃ Rotational elastic element
k₄, k₅, k₆ Linear elastic element

1. A computation device for simulating a robot system comprising a robot having a plurality of joints and a tool attached to the robot and configured to perform a predetermined task on a workpiece, the task being performed by causing at least one of a force or a torque generated by one of the tool or the workpiece to act on an other, the computation device comprising:
at least one processor; and
at least one memory, wherein
the memory stores a mathematical model in which at least one of the robot, the tool, or the workpiece is defined as an elastic element, and
the processor acquires input information including a posture of the robot, an arrangement of the tool and the workpiece, and a magnitude and a direction of at least one of the force or the torque and estimates a load or an amount of deformation in at least one of the robot, the tool, or the workpiece by using the acquired input information and the mathematical model stored in the memory.

2. The computation device for the robot system according to claim 1, wherein the processor determines whether or not the estimated load or amount of deformation is within a range of allowable values in each of the corresponding joints.

3. The computation device for the robot system according to claim 2, further comprising a display unit that displays a proportion of the estimated load or amount of deformation with respect to the allowable value.

4. The computation device for the robot system according to claim 3, wherein the display unit comprises a user interface that receives input of the input information.

5. The computation device for the robot system according to claim 2, wherein the processor searches for a posture of the robot that reduces the load when the estimated load is higher than the allowable value.

6. The computation device for the robot system according to claim 2, wherein the processor searches for an arrangement of the tool or the workpiece that reduces the load when the estimated load is higher than the allowable value.

7. The computation device for the robot system according to claim 1, wherein the processor acquires an actually measured value corresponding to the load or the amount of deformation, and adjusts, by using machine learning, a value corresponding to the elastic element in the mathematical model so that the load or the amount of deformation is closer to the actually measured value.
